(19) United States
(12) Patent Application Publication
(10) Pub. No.: US 2003/0041970 A1
(43) Pub. Date: Mar. 6, 2003

(54) Wafer processing machine

(75) Inventor: Steven T. Fink, Mesa, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: TOKYO ELECTRON LIMITED, Tokyo (JP)

(21) Appl. No.: 10/230,175

(22) Filed: Aug. 29, 2002

Related U.S. Application Data
(60) Provisional application No. 60/315,340, filed on Aug. 29, 2001.

(51) Int. Cl. C23F 1/00; C23C 16/00

(52) U.S. Cl. 156/345.32; 118/715; 118/719

(57) ABSTRACT

A system and method for processing plural wafers in a plasma processing system using a single upper electrode. By placing plural wafer holders into a single plasma processing chamber, the footprint of a resulting plasma chamber may be made smaller than the total footprint of an equivalent number of individual chambers. Moreover, pumping may be increased by placing plural pumps below the wafer holders, and preferably in positions not obstructed by the wafer holders.

### CROSS-REFERENCE TO RELATED APPLICATION

The present application claims priority to U.S. provisional application serial No. 60/315,340, filed on Aug. 29, 2001, the entire contents of which are herein incorporated by reference.

### BACKGROUND OF THE INVENTION

1. Field of the Invention

The present invention is directed to a design and implementation of a wafer processing machine and to a method of using the same.

2. Discussion of the Background

Manufacturers of semiconductor integrated circuits (ICs) are faced with intense competitive pressure to improve their products and as a result, pressure to improve the processes used to fabricate those products. This pressure in turn is driving the manufacturers of the equipment used by IC manufacturers to improve the value of their equipment, and in particular to reduce the operating cost to users of their equipment.

One such cost is the cost of the clean room. The larger the equipment, the larger the clean room and its associated costs. Thus, manufacturers strive to reduce the size of their manufactured equipment such that the total overhead cost of producing circuits in the clean room is also reduced.

### SUMMARY OF THE INVENTION

It is an object of the present invention to provide a plasma processing system utilizing a single upper electrode covering plural wafers on corresponding wafer holders.

It is another object of the present invention to provide a multi-wafer plasma processing chamber in which the gate valves controlling access to the pumping system are offset with respect to the wafer holders. In one such embodiment, a two-wafer system includes two wafer holders positioned, with respect to a unit circle, at zero and 180 degrees while the gate valves are positioned below the wafer holders at 90 and 270 degrees.

### BRIEF DESCRIPTION OF THE DRAWINGS

The invention is better understood by reading the following Detailed Description of the Preferred Embodiments with reference to the accompanying drawing figures, in which like reference numerals refer to like elements throughout, and in which:

FIG. 1 is a plan view of one embodiment of a plasma processing system according to the present invention;

FIG. 2 is a side view of the embodiment of the plasma processing system according to FIG. 1;

FIGS. 3A and 3B are top views of two upper electrode designs covering two wafer holders; and

FIGS. 4A and 4B are top views of two additional upper electrode designs covering two wafer holders.

### DETAILED DESCRIPTION OF THE PREFERRED EMBODIMENTS

In describing preferred embodiments of the present invention illustrated in the drawings, specific terminology is employed for the sake of clarity. However, the invention is not intended to be limited to the specific terminology so selected, and it is to be understood that each specific element includes all technical equivalents that operate in a similar manner to accomplish a similar purpose.

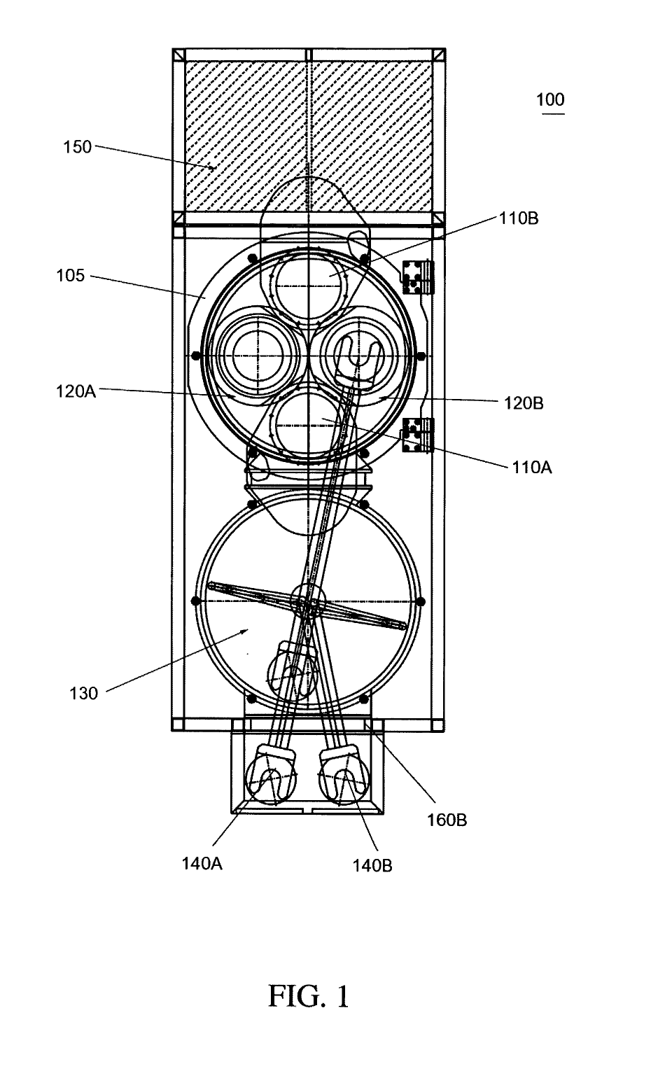

FIG. 1 is a plan view of one embodiment of a plasma processing system according to the present invention. In that embodiment, a plasma processing system 100 generally includes (1) a plasma processing chamber 105, (2) a robot 130 for moving wafers into and out of the chamber 105, and (3) the electronics 150 for controlling the processing of wafers within the chamber 105. The chamber 105 generally includes (A) series of gate valves 110A and 110B positioned and connecting to a bottom of the system 100 and (B) wafer holders 120A and 120B (also known as “chucks”). (Although the phrase “wafer holder” is used throughout for illustrative purposes, the holder may actually hold any type of work piece to be processed, e.g., an LCD panel.) The robot arm 135 of the robot 130 removes wafers from a cassette (140A or 140B) and places them, one at a time, on an available one of the wafer holders (either 120A or 120B). The wafers are then simultaneously processed within the chamber 105 and returned, one at a time, to a corresponding cassette (140A or 140B) using the robot arm 135.

In order to maintain the proper processing environment (including pressures), the chamber 105 is sealed off from the robot 130 and its associated chamber (commonly referred to as the substrate transfer chamber) by way of a slot valve 160A. This enables the robot 130 and its associated chamber to be “pumped down” to the pressure of the processing chamber before attempting to place wafers into or remove wafers from the process chamber 105. Similarly, the robot 130 can be brought back to atmospheric pressure before attempting to place wafers into or remove wafers from a cassette (140A or 140B) via slot valve 160B. Such pumping actions can be performed by vacuum components 175 housed within the system 100. The various methods of equalizing pressure between chambers to accommodate substrate transfer are well known to those of skill in the art.

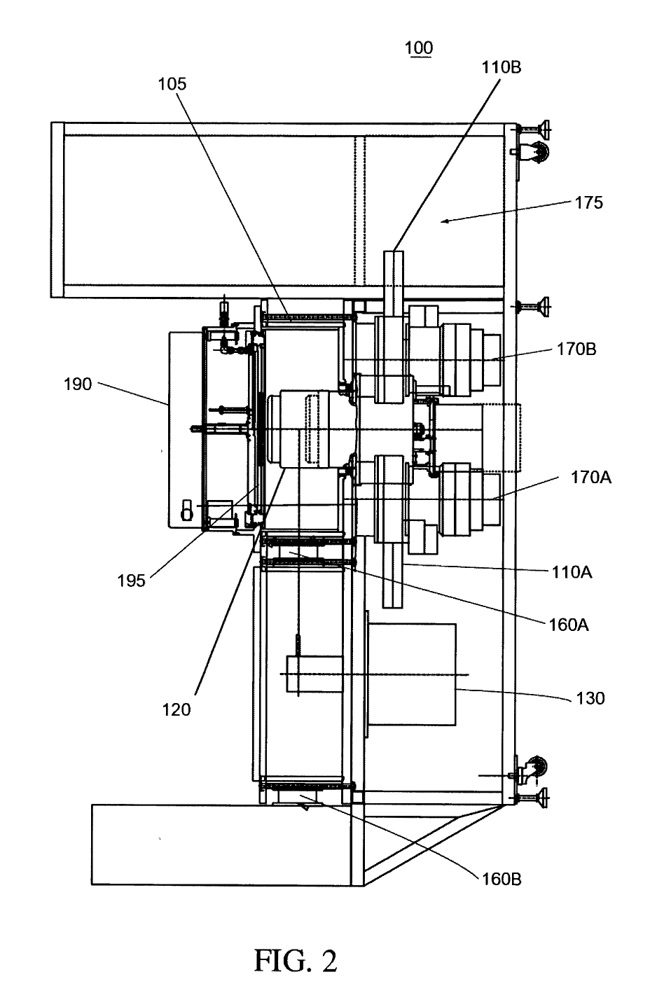

As shown in FIG. 2, the gate valves 110A and 110B provide access to corresponding vacuum pumps (170A and 170B) to draw gas out of the chamber 105 during processing. Vacuum pumps 170A, 170B are preferably turbo-molecular vacuum pumps (TMP) capable of a pumping speed up to 5000 liters per second or greater. In conventional plasma processing devices utilized for dry plasma etch, a 1000 to 3000 liter per second TMP is employed. TMPs are useful for low pressure processing, typically less than 50 mTorr. At higher pressures, the TMP pumping speed falls off dramatically. For high pressure processing (e.g., processing greater than 100 mTorr), a mechanical booster pump and dry roughing pump is recommended. An exemplary TMP is a 3300 liter/second vacuum pump offered by Mitsubishi (Model #FT3300W). By providing two pumps in the positions shown, increased gas flow is achieved while providing a smaller footprint compared to two separate plasma processing chambers. As would be understood by one of ordinary skill in the art, the exact size and position of the gate valves can be different than shown in FIGS. 1 and 2. Generally, at least a portion of the space left empty by the placement of the wafer holders 120 should be utilized as the gate valves. (Although only one gate valve may be used in some embodiments, the chamber 105 preferably maintains a generally uniform flow over the wafers being processed to ensure uniform processing.) Moreover, although the process chamber 105 is larger than either of the two chambers that it replaces, the pumping conductance is better in light of the less obstructed flow path as compared to a side mounted pump and, therefore, better flow conductance between the processing region and pump inlet.

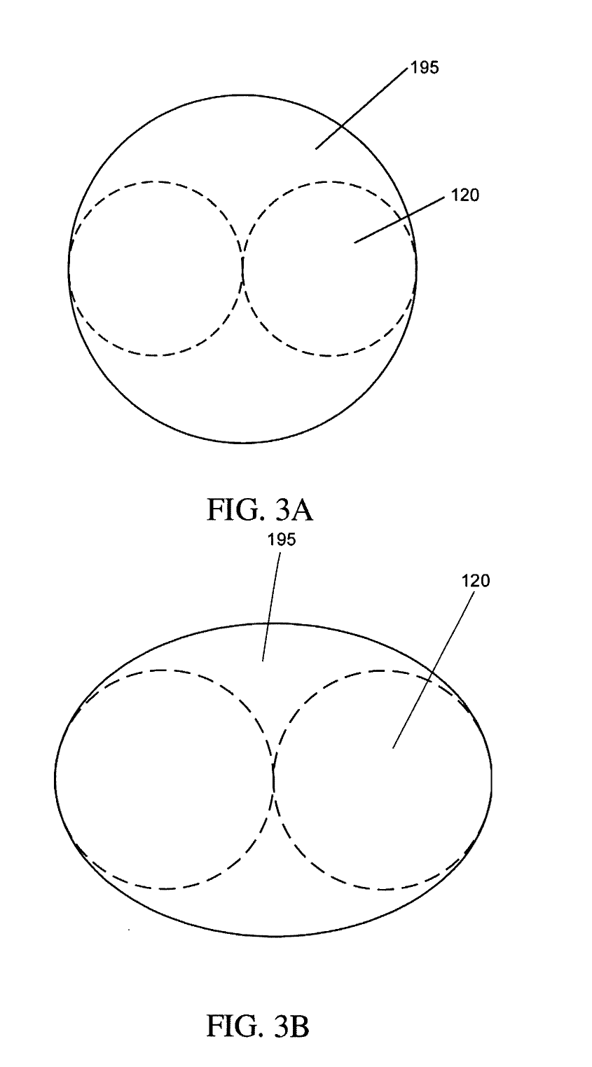

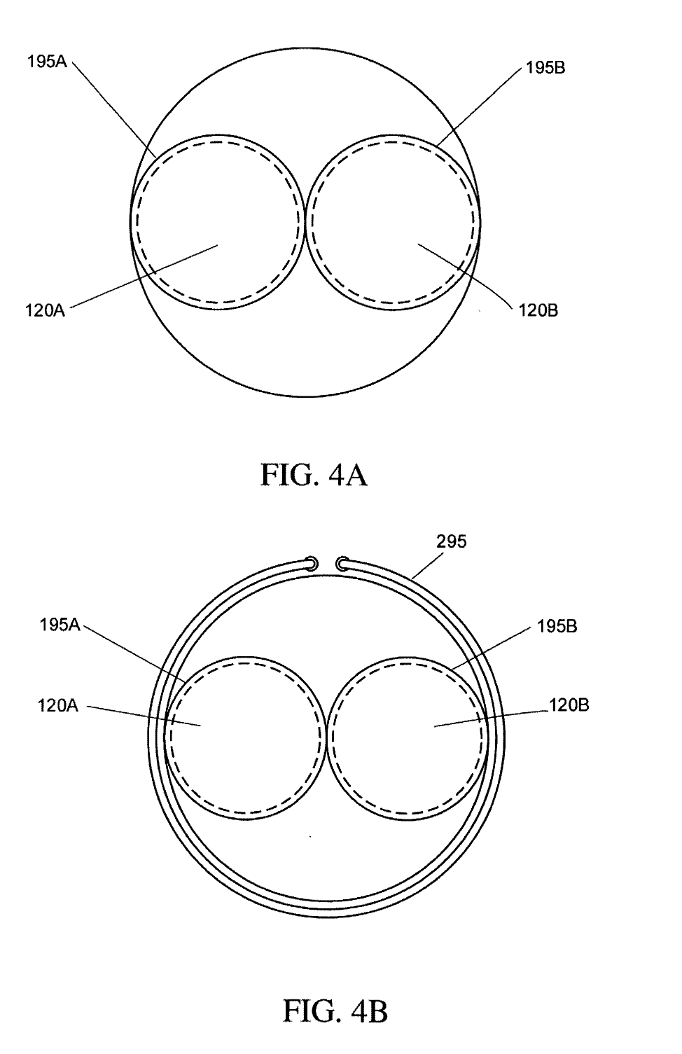

As shown in FIG. 2, a single upper electrode assembly 190 can be utilized (as compared with two separate assemblies when utilizing independent chambers). The electrode assembly 190 includes an upper electrode 195 that covers both wafer holders 120A and 120B. The upper electrode 190 can either be circular, as shown in FIG. 3A, or of a shape that reduces the size and/or cost of the upper electrode 190 while still covering both wafer holders 120A and 120B. One such embodiment is an oval, although a more “figure-8” like structure is also possible. In an alternate embodiment, a plurality of electrodes 195 (195A and 195B; see FIG. 4A) are employed, one for each wafer holder (120A, 120B), and directly opposing each wafer holder (120A, 120B). The corresponding diameter of each electrode 195 can be similar to that of the wafer holder (120A, 120B) or larger. Further, in an alternate embodiment, radio frequency (RF) power is applied to electrode 195 via RF generator and impedance match network to form a plasma to assist material processing of the substrates on wafer holders 120A and 120B. RF power can be applied in a frequency range from 10 MHz to 200 MHz at power levels ranging from 1 to 5 kW. The impedance match network serves to maximize the transfer of power to the plasma. The above design and implementation is well known to those skilled in the art.

In an alternate embodiment, the electrode 195 is grounded. In an alternate embodiment, the electrode 195 is grounded and an inductive coil 295 (see FIG. 4B) surrounds the chamber 105, to which RF power is coupled in order to form a plasma via inductive coupling.

In an alternate embodiment, both an inductive coil 295 (see FIG. 4B) and the electrode 195 are driven with RF power.

In an alternate embodiment, the electrode 195 further serves as a gas injection electrode through which process gas is injected into the processing region adjacent each substrate. One such gas injection design is commonly referred to as a showerhead gas injection system comprising a plurality of gas injection orifices coupled to a gas delivery system, there between a common plenum (or plurality of gas plenums) and a series of baffle plates is inserted to distribute the gas flow.

The substrate(s) can be transferred into and out of chamber 105 through slot valve 160A (as described above) via robotic substrate transfer system 130 where it is received by substrate lift pins (not shown) housed within substrate holder (120A, 120B) and mechanically translated by devices housed therein. Once a substrate is received from robot 130 (substrate transfer system), it is lowered to an upper surface of a substrate holder (120A, 120B) and affixed to substrate holder (120A, 120B) via an electrostatic clamp (not shown). Moreover, gas can be delivered to the back-side of the substrate to improve the gas-gap thermal conductance between a given substrate and substrate holder (120A, 120B). Moreover, RF power can be applied to each substrate holder 120A, 120B via a RF generator and impedance match network. As before, such design and implementation is well known to those skilled in the art.

Modifications and variations of the above-described embodiments of the present invention are possible, as appreciated by those skilled in the art in light of the above teachings. It is therefore to be understood that, within the scope of the appended claims and their equivalents, the invention may be practiced otherwise than as specifically described.

1. A plasma processing chamber comprising:
at least two wafer holders;
a single upper electrode covering both of the at least two wafer holders; and
at least one gate valve located at a bottom of the plasma processing chamber.

2. The plasma processing chamber as claimed in claim 1, further comprising at least one turbo molecular pump coupled to the at least one gate valve.

3. A plasma processing system comprising:
(a) a plasma processing chamber including:
at least two wafer holders;
a single upper electrode covering both of the at least two wafer holders; and
at least one gate valve located at a bottom of the plasma processing chamber; and
(b) a robot arm for placing wafers onto and removing wafers from the at least two wafer holders.

4. The plasma processing system as claimed in claim 3, further comprising at least one cassette holder for providing wafers to and receiving wafers from the robot arm.

5. The plasma processing system as claimed in claim 3, further comprising a slot valve for separating the plasma processing chamber from the robot arm during processing.

6. The plasma processing system as claimed in claim 5, further comprising a pump for equalizing a pressure between the robot arm and the plasma processing chamber prior to transferring a wafer between the robot arm and the plasma processing chamber.

7. A method of processing plural wafers simultaneously within a single processing chamber, comprising the steps of:
placing plural wafers onto at least two wafer holders; and
generating a plasma above both of the at least two wafer holders using a single upper electrode covering both of the at least two wafer holders.
